(19) United States
(12) Patent Application Publication
(10) Pub. No.: US 2023/0253526 A1
(43) Pub. Date: Aug. 10, 2023

(54) SEMICONDUCTOR LIGHT-EMITTING ELEMENT

(71) Applicant: ROHM Co., LTD., Kyoto (JP)

(72) Inventors: Ryosuke Ishimaru, Kyoto (JP); Kazuaki Tsutsumi, Kyoto (JP); Takao Fujimori, Kyoto (JP)

(21) Appl. No.: 18/159,774

(22) Filed: Jan. 26, 2023

(30) Foreign Application Priority Data
Feb. 7, 2022 (JP) 2022-017277

(51) Int. Cl. H01L 33/12; H01L 33/20; H01L 33/32

(52) U.S. Cl. CPC H01L 33/12; H01L 33/20; H01L 33/32

(57) ABSTRACT

A semiconductor light-emitting element includes a substrate having a first surface, a plurality of protrusions disposed, with spacing opened between one another, on the first surface, a buffer layer disposed to cover the plurality of protrusions and the first surface positioned between the plurality of protrusions, a dimension of the buffer layer in a first direction orthogonal to the first surface being smaller than a dimension in the first direction of each of the plurality of protrusions, an n-type semiconductor layer that is disposed on the buffer layer and is doped with an n-type impurity, an active layer disposed on the n-type semiconductor layer, and a p-type semiconductor layer that is disposed on the active layer and is doped with a p-type impurity.

### CROSS REFERENCE TO RELATED APPLICATIONS

This application claims priority benefit of Japanese Patent Application No. JP 2022-017277 filed in the Japan Patent Office on Feb. 7, 2022. Each of the above-referenced applications is hereby incorporated herein by reference in its entirety.

### BACKGROUND

The present technology pertains to a semiconductor light-emitting element.

Japanese Patent No. 5366518 discloses a semiconductor light-emitting element that includes a substrate, protective films disposed on the substrate, an n-type semiconductor layer that is doped with an n-type impurity and is disposed on the substrate sandwiched by the protective films as well as on the protective films, an active layer disposed on the n-type semiconductor layer, and a p-type semiconductor layer that is disposed on the active layer and is doped with a p-type impurity. The n-type semiconductor layer is formed by selective lateral epitaxial growth.

### SUMMARY

The inventors founds a technique that, in comparison to the semiconductor light-emitting element described in Japanese Patent No. 5366518, enables the crystallinity of an n-type semiconductor layer to be further homogenized and enables a surface of the n-type semiconductor layer in contact with an active layer to be further planarized.

It is desirable to provide a semiconductor light-emitting element in which a surface of an n-type semiconductor layer in contact with an active layer is planarized.

A semiconductor light-emitting element according to the present technology includes a substrate having a first surface, a plurality of protrusions disposed, with spacing opened between one another, on the first surface, a buffer layer disposed to cover the plurality of protrusions and the first surface positioned between the plurality of protrusions, a dimension of the buffer layer in a first direction orthogonal to the first surface being smaller than a dimension in the first direction of each of the plurality of protrusions, an n-type semiconductor layer that is disposed on the buffer layer and is doped with an n-type impurity, an active layer disposed on the n-type semiconductor layer, and a p-type semiconductor layer that is disposed on the active layer and is doped with a p-type impurity. The substrate has a hexagonal crystal structure or a diamond crystal structure. The first surface is a (0001) plane of the hexagonal crystal structure or a (111) plane of the diamond crystal structure. The n-type semiconductor layer has a hexagonal crystal structure. When the first surface is in a plan view, an imaginary straight line that passes through respective centers of a first protrusion and a second protrusion that are adjacent to each other and are from among the plurality of protrusions is orthogonal to an (11-20) plane of the hexagonal crystal structure or a (1-12) plane of the diamond crystal structure of the substrate.

According to the present technology, it is possible to provide a semiconductor light-emitting element in which a surface of an n-type semiconductor layer in contact with an active layer is planarized.

### BRIEF DESCRIPTION OF THE DRAWINGS

FIG. 1 is a cross-sectional view for describing a semiconductor light-emitting element according to a first embodiment;

FIG. 2 is a plan view for describing a relation between a plane orientation for a substrate having a hexagonal crystal structure and an arrangement of a plurality of protrusions, in the semiconductor light-emitting element illustrated in FIG. 1;

FIG. 3 is a plan view for describing a relation between a plane orientation for the substrate having a hexagonal crystal structure and an arrangement of the plurality of protrusions, in the semiconductor light-emitting element illustrated in FIG. 1;

FIG. 4 is a view for describing an “a” plane and a “c” plane for a hexagonal crystal structure;

FIG. 5 is a plan view for describing a wafer prepared as a substrate having a hexagonal crystal structure, in a method of manufacturing the semiconductor light-emitting element according to the first embodiment;

FIG. 6 is a cross-sectional view for describing a step for forming a plurality of protrusions on the prepared wafer, in the method of manufacturing the semiconductor light-emitting element according to the first embodiment;

FIG. 7 is a plan view for describing a relation between a plane orientation for the wafer and an arrangement of the plurality of protrusions, in the step illustrated in FIG. 6;

FIG. 8 is a cross-sectional view for describing one step after the step illustrated in FIG. 6, in the method of manufacturing the semiconductor light-emitting element according to the first embodiment;

FIG. 9 is a cross-sectional view for describing one step after the step illustrated in FIG. 8, in the method of manufacturing the semiconductor light-emitting element according to the first embodiment;

FIG. 10 is a cross-sectional view for describing one step after the step illustrated in FIG. 9, in the method of manufacturing the semiconductor light-emitting element according to the first embodiment;

FIG. 11 is a cross-sectional view for describing one step after the step illustrated in FIG. 10, in the method of manufacturing the semiconductor light-emitting element according to the first embodiment;

FIG. 12 is a cross-sectional view for describing one step after the step illustrated in FIG. 11, in the method of manufacturing the semiconductor light-emitting element according to the first embodiment;

FIG. 13 is a view for describing a relation between a unit cell of a (0001) plane of the substrate having the hexagonal crystal structure and a unit cell of a (0001) plane of an n-type semiconductor layer having a hexagonal crystal structure, in the semiconductor light-emitting element according to the first embodiment;

FIG. 14 is a plan view for describing a relation different to the relation illustrated in FIG. 2, for the relation between the plane orientation of a substrate having a hexagonal crystal structure and the arrangement of a plurality of protrusions;

FIG. 15 is a plan view for describing a relation between a plane orientation for a substrate having a diamond crystal structure and an arrangement of a plurality of protrusions, in a semiconductor light-emitting element according to a second embodiment;

FIG. 16 is a view for describing a relation between an atomic arrangement of a (111) plane of the substrate having the diamond crystal structure and an atomic arrangement a (0001) plane of an n-type semiconductor layer having a hexagonal crystal structure, in the semiconductor light-emitting element according to the second embodiment;

FIG. 17 is a cross-sectional view for describing a semiconductor light-emitting element according to a third embodiment; and

FIG. 18 is a cross-sectional view for describing a variation of the semiconductor light-emitting element according to the third embodiment.

### DETAILED DESCRIPTION OF THE PREFERRED EMBODIMENTS

Description is given below regarding embodiments of the present technology, with reference to the drawings. Each drawing indicates coordinate axes for the convenience of the description. In each drawing, an X axis, a Y axis, and a Z axis are orthogonal to each other.

In a case where geometric language and language representing a position, direction, or size relation, for example, language such as “orthogonal,” “parallel,” “along,” or “equal” is used in the present embodiment, such language permits manufacturing error or slight variation.

A crystal orientation used in the present embodiment is a generic term for crystallographically equivalent planes. In addition, the crystal orientation used in the present embodiment permits manufacturing error or slight variation.

### First Embodiment

<Configuration of Semiconductor Light-Emitting Element>

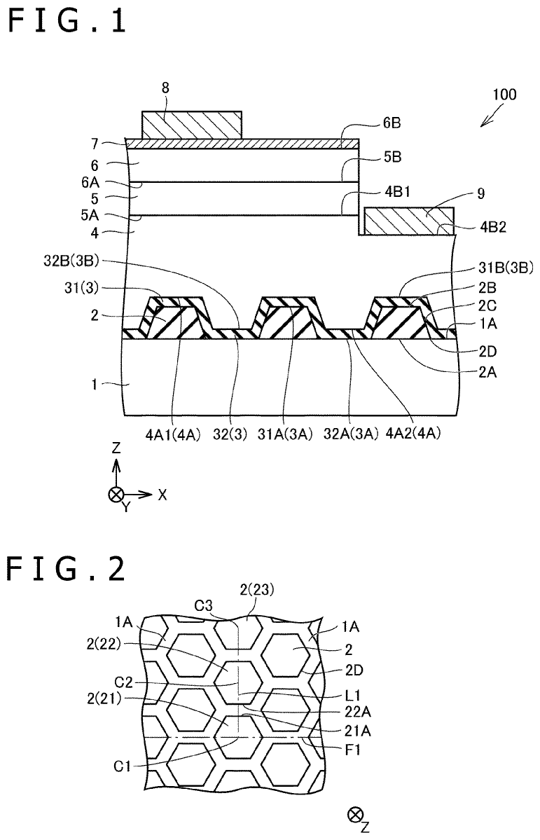

As illustrated in FIG. 1, a semiconductor light-emitting element 100 according to a first embodiment is mainly provide with a substrate 1, a plurality of protrusions 2, a buffer layer 3, an n-type semiconductor layer 4, an active layer 5, a p-type semiconductor layer 6, a first electrode section 7, a second electrode section 8, and a third electrode section 9.

The substrate 1 has a first surface 1A. The plurality of protrusions 2, the buffer layer 3, the n-type semiconductor layer 4, the active layer 5, the p-type semiconductor layer 6, the first electrode section 7, and the second electrode section 8 are disposed on the first surface 1A. The first surface 1A extends along the X axis direction and the Y axis direction, and is orthogonal to the Z axis direction (a first direction). It is assumed below that the direction in which the first surface 1A faces is upward and the direction opposite thereto is downward.

A material included in the first surface 1A of the substrate 1 has a hexagonal crystal structure (refer to FIG. 4). The first surface 1A of the substrate 1 is a (0001) plane (“c” plane) of the hexagonal crystal structure. Note that an orientation error with respect to the (0001) plane is permitted for the plane orientation of the first surface 1A. An absolute value for permitted orientation error is greater than or equal to 0° and less than or equal to 10°. The material included in the first surface 1A of the substrate 1 may be any material having a hexagonal crystal structure, and, for example, includes sapphire, silicon carbide (SiC), gallium nitride (GaN), or ScAlMgO₄ (SCAM).

The plurality of protrusions 2 are disposed on the first surface 1A with spacing opened between one other. In a plan view, the plurality of protrusions 2 are periodically disposed in two dimensions. A plan view means a field of view in which the first surface 1A is viewed from above. In other words, in the present embodiment, the plan view means a field of view in which viewing is performed in a c-axis direction for the hexagonal crystal structure of the substrate 1. An arrangement of the plurality of protrusions 2 is described below.

Each of the plurality of protrusions 2 has, for example, a bottom surface 2A that is connected to the first surface 1A, a top surface 2B disposed upward from the bottom surface 2A, and side surfaces 2C that connect between the bottom surface 2A and the top surface 2B. The bottom surface 2A is in contact with the first surface 1A, for example. The top surface 2B and the side surfaces 2C protrude upward from the first surface 1A. The interior angles formed by the bottom surface 2A and the side surfaces 2C are acute angles, for example. The interior angles formed by the bottom surface 2A and the side surfaces 2C are greater than or equal to 30° and less than or equal to 60°, for example. The first surface 1A of the substrate 1 and the top surface 2B and the side surfaces 2C of the plurality of protrusions 2 have an uneven shape.

A dimension in the Z axis direction for each of the plurality of protrusions 2, in other words, a minimum distance in the Z axis direction between the bottom surface 2A and the top surface 2B for each of the plurality of protrusions 2, is the same as one another, for example. A thickness of each of the plurality of protrusions 2 is greater than or equal to 10 nm and less than or equal to 5 μm, for example.

In a cross-section along the Z axis, the external shape of each of the plurality of protrusions 2 may be any shape that does not inhibit the formation of the n-type semiconductor layer 4 by using an epitaxial lateral overgrowth (ELOG) method, and is a trapezoid, for example. The width of the bottom surface 2A in the X direction may be wider than the width of the top surface 2B in the X direction, for example. The width of the bottom surface 2A in the Y direction may be wider than the width of the top surface 2B in the Y direction, for example. In other words, each of the plurality of protrusions 2 has a shape that tapers as a distance increases from the first surface 1A of the substrate 1 in the above-mentioned cross-sectional view, for example.

In the plan view, the external shape of each of the plurality of protrusions 2 may be any shape that does not inhibit formation of the n-type semiconductor layer 4 by using the ELOG method, and is a hexagonal shape, for example. In other words, the external shape of a lower end 2D of the side surfaces 2C of each of the plurality of protrusions 2 is a hexagonal shape, for example. The external shape of the top surface 2B of each of the plurality of protrusions 2 may be any shape, and is a hexagonal shape, for example. The external shape of the top surface 2B of each of the plurality of protrusions 2 is similar to the external shape of the bottom surface 2A of each of the plurality of protrusions 2, for example.

Note that, in a cross-section along the Z axis, the external shape of each of the plurality of protrusions 2 may be a triangular shape, a square shape, or a rectangular shape, for example. In the plan view, the external shape of each of the plurality of protrusions 2 may be a triangular shape, a square shape, a rectangular shape, a circular shape, or an oval shape, for example. The external shape of the bottom surface 2A of each of the plurality of protrusions 2 may be different to the external shape of the top surface 2B of each of the plurality of protrusions 2.

The plurality of protrusions 2 are transparent with respect to an emission wavelength for the semiconductor light-emitting element 100. The emission wavelength is the wavelength (peak wavelength of emitted light) for which the intensity is greatest, from among light generated by electrons supplied from the n-type semiconductor layer 4 to the active layer 5 recombining with holes supplied from the p-type semiconductor layer 6 to the active layer 5.

A material included in each of the plurality of protrusions 2 includes at least one selected from the group consisting of silicon oxide (SiO₂), silicon nitride (Si₃N₄), silicon oxynitride (Sion), titanium oxide (TiO₂), alumina (Al₂O₃), and magnesium fluoride (MgF₂). The material included in each of the plurality of protrusions 2 desirably includes SiO₂. In this case, in contrast with a case in which the material included in each of the plurality of protrusions 2 is sapphire, it is possible to constrain the refractive index of the plurality of protrusions 2 to be low, and improving the light extraction efficiency of the semiconductor light-emitting element 100 is predicted.

The buffer layer 3 is disposed so as to cover the plurality of protrusions 2 as well as the first surface 1A that is positioned between the plurality of protrusions 2. The buffer layer 3 includes a first portion 31 disposed above each of the plurality of protrusions 2 and a second portion 32 disposed between two adjacent protrusions 2. The dimension (thickness) in the Z axis direction for each first portion 31 and second portion 32 of the buffer layer 3 is smaller than the dimension in the Z axis direction of each of the plurality of protrusions 2. The thickness of each first portion 31 and second portion 32 of the buffer layer 3 is greater than or equal to 5 nm and less than or equal to 200 nm.

The buffer layer 3 has a bottom surface 3A and a top surface 3B. The bottom surface 3A has a bottom surface 31A for each first portion 31 and a bottom surface 32A for each second portion 32. The bottom surface 31A of the first portions 31 has regions in contact with the side surfaces 2C of each of the plurality of protrusions 2, and regions in contact with the top surface 2B of each of the plurality of protrusions 2. The bottom surface 32A of each second portion 32 is in contact with the first surface 1A.

The top surface 3B has a top surface 31B for each first portion 31 and a top surface 32B for each second portion 32. The top surface 31B of the first portion 31 protrudes upward from the top surface 3B of the second portion 32. The top surface 3B of the buffer layer 3 has an uneven shape due to the uneven shape of the first surface 1A of the substrate 1 as well as the uneven shape of the top surfaces 2B and the side surfaces 2C of the plurality of protrusions 2. The top surface 3B of the buffer layer 3 is in contact with a bottom surface 4A of the n-type semiconductor layer 4.

A material included in the buffer layer 3 includes aluminum nitride (Aln), for example.

The n-type semiconductor layer 4 is disposed on the buffer layer 3. The n-type semiconductor layer 4 is doped with an n-type impurity. The n-type semiconductor layer 4 has a hexagonal crystal structure. A material included in the n-type semiconductor layer 4 is GaN, for example. The n-type impurity is silicon (Si), for example. A concentration of impurities in the n-type semiconductor layer 4 is not particularly limited, and is, for example, greater than or equal to 5×10¹⁷ cm⁻³ and less than or equal to 5×10¹⁹ cm⁻³.

The n-type semiconductor layer 4 has the bottom surface 4A, a first top surface 4B1 (a second surface), and a second top surface 4B2. The bottom surface 4A has a region 4A1 that is in contact with the top surface 31B of each first portion 31 of the buffer layer 3 and a region 4A2 that is in contact with the top surface 32B of each second portion 32. The first top surface 4B1 is in contact with a bottom surface 5A of the active layer 5. The second top surface 4B2 is disposed lower than the first top surface 4B1 and is in contact with the third electrode section 9. The region 4A2 in the bottom surface 4A as well as the first top surface 4B1 and the second top surface 4B2 are each a (0001) plane for a hexagonal crystal structure.

The top surface 4B1 (second surface) is a flat surface. A “flat surface” means a surface for which an arithmetic mean roughness Ra which is stipulated in Japanese Industrial Standards (JIS) B 0601 is less than or equal to 0.1 μm. The arithmetic mean roughness Ra of the top surface 4B1 can be measured using a non-contact three-dimensional measurement apparatus that uses a laser, for example.

The dimension (thickness) in the Z axis direction of the n-type semiconductor layer 4 is greater than the dimension (thickness) in the Z axis direction of each of the plurality of protrusions 2. The thickness of the n-type semiconductor layer 4 is, for example, greater than or equal to 1 μm and less than or equal to 20 μm.

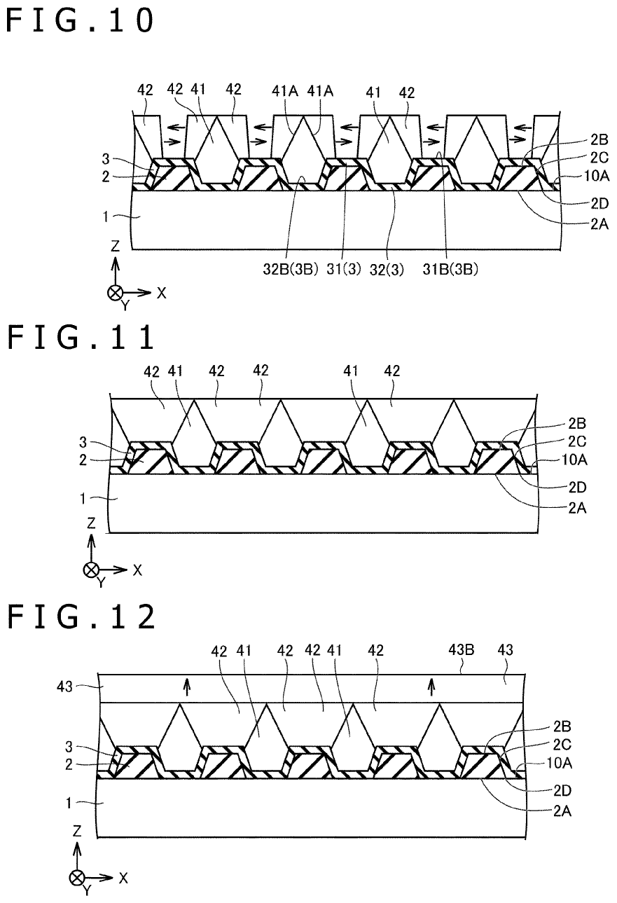

The n-type semiconductor layer 4 includes a plurality of three-dimensional growth layers 41 (refer to FIG. 9), a plurality of first two-dimensional growth layers 42 (refer to FIG. 10 and FIG. 11), and one second two-dimensional growth layer 43 (refer to FIG. 12). In other words, the n-type semiconductor layer 4 is formed by using the ELOG method.

Each of the plurality of three-dimensional growth layers 41 is grown on top of the top surface 32B of a second portion 32 of the buffer layer 3. The region 4A2 in the bottom surface 4A of the n-type semiconductor layer 4 is formed by each of the plurality of three-dimensional growth layers 41.

The plurality of first two-dimensional growth layers 42 are respectively grown on the top surface 31B of each first portion 31 of the buffer layer 3 so as to be embedded between the plurality of three-dimensional growth layers 41. The region 4A1 in the bottom surface 4A of the n-type semiconductor layer 4 is formed by each of the plurality of first two-dimensional growth layers 42.

The second two-dimensional growth layer 43 is grown on each of the plurality of three-dimensional growth layers 41 and plurality of first two-dimensional growth layers 42. The first top surface 4B1 and the second top surface 4B2 of the n-type semiconductor layer 4 are configured by the second two-dimensional growth layer 43.

The active layer 5 is disposed on the n-type semiconductor layer 4. The active layer 5 has the bottom surface 5A and a top surface 5B. The top surface 5B is in contact with a bottom surface 6A of the p-type semiconductor layer 6. The active layer 5 has a multi-quantum well (MQW) structure. The active layer 5 includes well layers and barrier layers that have a bandgap greater than that of the well layers are disposed so as to sandwich respective well layers.

A material included in the well layers in the active layer 5 includes indium gallium nitride (InGaN), for example. The material included in the barrier layers in the active layer 5 includes GaN, for example.

The p-type semiconductor layer 6 is disposed on the active layer 5. The p-type semiconductor layer 6 is doped with a p-type impurity. The p-type semiconductor layer 6 has a hexagonal crystal structure. A material included in the p-type semiconductor layer 6 is GaN, for example. The p-type impurity is Mg, for example. A concentration of impurities in the p-type semiconductor layer 6 is not particularly limited, and is, for example, greater than or equal to 1×10¹⁸ cm⁻³ and less than or equal to 1×10²² cm⁻³.

The p-type semiconductor layer 6 has the bottom surface 6A and a top surface 6B. The top surface 6B is in contact with the first electrode section 7. The bottom surface 6A and top surface 6B of the p-type semiconductor layer 6 are (0001) planes for a hexagonal crystal structure.

The p-type semiconductor layer 6 may be configured as a laminate having a plurality of p-type semiconductor layers with mutually different impurity concentrations. The p-type semiconductor layer 6 may, for example, include a first p-type semiconductor layer that is in contact with the top surface of the active layer 5 and a second p-type semiconductor layer that is in contact with the top surface of the first p-type semiconductor layer and has a higher impurity concentration than that of the first p-type semiconductor layer.

The first electrode section 7 is disposed on the p-type semiconductor layer 6. The first electrode section 7 is in ohmic contact with the p-type semiconductor layer 6. The first electrode section 7 is provided as a generally-called transparent electrode. The material included in the first electrode section 7 includes at least one of zinc oxide (ZnO) and indium tin oxide (ITO), for example. The material included in the first electrode section 7 may be Zeno doped with at least one of gallium (Ga) and aluminum (Al), or Zeno that includes indium (In).

The second electrode section 8 is electrically connected with the p-type semiconductor layer 6 via the first electrode section 7. The second electrode section 8 is in ohmic contact with the first electrode section 7. A material included in the second electrode section 8 includes at least one selected from the group consisting of Al, palladium (Pd), gold (Au), titanium (Ti), nickel (Ni), chromium (Cr), and tin (Sn), for example.

The third electrode section 9 is disposed on the second top surface 4B2 of the n-type semiconductor layer 4. The third electrode section 9 is in ohmic contact with the n-type semiconductor layer 4. A material included in the third electrode section 9 includes at least one selected from the group consisting of Al, Au, Ti, Ni, Cr, and Sn, for example.

<Arrangement of Plurality of Protrusions 2>

With reference to FIG. 2, the plurality of protrusions 2 have a first protrusion 21 and a second protrusion 22 that is adjacent to the first protrusion 21. In FIG. 2, a first broken line L1 indicates an imaginary straight line that passes through a center C1 of the first protrusion 21 and a center C2 of the second protrusion 22, in a plan view. A second broken line F1 indicates an extension direction for an (11-20) plane (“a” plane) of the hexagonal crystal structure held by the substrate 1, in the plan view. The first broken line L1 and the second broken line F1 can be expressed on an image obtained by using a scanning electron microscope (SEM) to observe the semiconductor light-emitting element 100, for example. For example, the first broken line L1 can be expressed on the image as a line segment passing through the centers of two protrusions 2 optionally selected from among the plurality of protrusions 2. The second broken line F1 can be expressed on the image on the basis of an (11-20) plane of the substrate 1 in the semiconductor light-emitting element 100 identified by using X-ray diffraction (XRD).

In FIG. 2, the outline of each of the plurality of protrusions 2 indicates a lower end 2D of the side surfaces 2C of each of the plurality of protrusions 2.

As illustrated in FIG. 2, the first broken line L1 is orthogonal to the second broken line F1 in the plan view. In other words, the imaginary straight line L1 that passes through the centers of the first protrusion 21 and the second protrusion 22 is orthogonal to the (11-20) plane of the hexagonal crystal structure held by the substrate 1. “Orthogonal” here means that the angle the imaginary straight line L1 forms with respect to the (11-20) plane in the plan view is greater than or equal to 80° and less than or equal to 100°. The angle the imaginary straight line L1 forms with respect to the (11-20) plane in the plan view is desirably greater than or equal to 85° and less than or equal to 95°.

As illustrated in FIG. 2, a minimum distance between two adjacent protrusions 2 from among the plurality of protrusions 2 is mutually the same, for example. Planar dimensions for each of the plurality of protrusions 2 are mutually the same, for example.

As illustrated in FIG. 2, the external shape of each of the plurality of protrusions 2 is, for example, a regular hexagonal shape in the plan view. In the plan view, an edge 21A that is closest to the second protrusion 22 from among the six edges that form the outline of the first protrusion 21 is parallel to an edge 22A that is closest to the first protrusion 21 from among the six edges that form the outline of the second protrusion 22. “Parallel” here means that the absolute value of an angle formed by the edge 21A and the edge 22A is greater than or equal to 0° and less than or equal to 10°.

As illustrated in FIG. 2, each of the edge 21A of the first protrusion 21 and the edge 22A of the second protrusion 22 is parallel to the (11-20) plane of the substrate 1, for example. “Parallel” here means that the absolute value of the angle that each of the edge 21A of the first protrusion 21 and the edge 22A of the second protrusion 22 form with respect to the second broken line F1 is greater than or equal to 0° and less than or equal to 10°.

As illustrated in FIG. 2, the imaginary straight line L1 is orthogonal to each of the edge 21A of the first protrusion 21 and the edge 21B of the second protrusion 22. “Orthogonal” here means that the angle that each of the edge 21A and the edge 22A form with respect to the imaginary straight line L1 is greater than or equal to 80° and less than or equal to 100°.

The first protrusion 21 and the second protrusion 22 can be optionally selected from the plurality of protrusions 2 illustrated in FIG. 2.

Referring to FIG. 2, a protrusion 2 that is from among the plurality of protrusions 2, is adjacent to the second protrusion 22, and is positioned on the reverse side to the first protrusion 21 with respect to the second protrusion 22 is referred to as a third protrusion 23. The imaginary straight line L1 also passes through a center C3 of the third protrusion 23. In other words, the imaginary straight line L1 that passes through the centers of the second protrusion 22 and the third protrusion 23 is orthogonal to the (11-20) plane of the hexagonal crystal structure held by the substrate 1. Accordingly, the imaginary straight line L1 can be expressed on FIG. 2 as a straight line that passes through the centers of a group of protrusions 2 optionally selected from a plurality of groups of protrusions 2 that are adjacent to each other with the centers of each group being lined up and disposed on the same straight line.

In addition, in the present embodiment as described above, because a crystal orientation is a generic term for planes that are crystallographically equivalent, the plane orientation of the substrate 1 which has a hexagonal crystal structure is a generic term for six planes that are mutually equivalent to each other. The second broken line F1 which expresses an extension direction for the (11-20) plane can be expressed on FIG. 2 as a straight line indicating the extension direction for any plane from among six mutually equivalent planes.

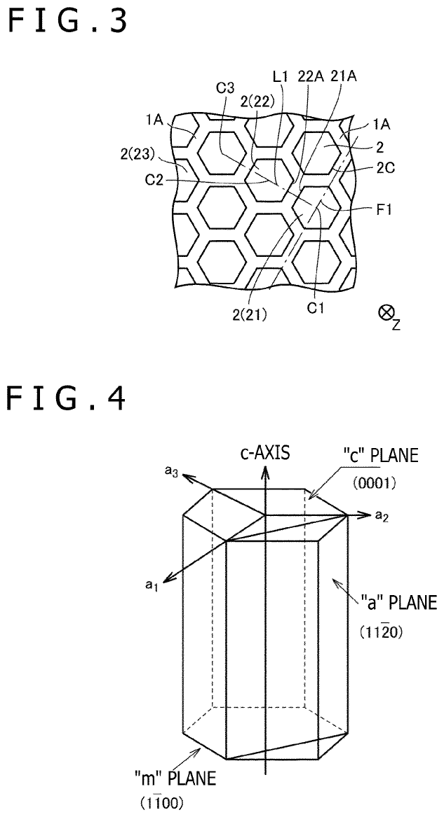

FIG. 3 is a view for, in the same field of view as in FIG. 2, indicating that the first broken line L1 and the second broken line F1 can be expressed by a different aspect to that in FIG. 2. As illustrated in FIG. 3, even in a case where two protrusions 2 that differ from that in FIG. 2 are selected as the first protrusion 21 and the second protrusion 22 from the plurality of protrusions 2 illustrated in FIG. 2, the imaginary straight line L1 passing through the center C1 of the first protrusion 21 and the center C2 of the second protrusion 22 is orthogonal to the second broken line F1 extending along the extension direction for planes equivalent to “a” plane indicated by the second broken line F1 in FIG. 2. For example, in a case where the second broken line F1 illustrated in FIG. 2 indicates the extension direction for the (11-20) plane, the second broken line F1 illustrated in FIG. 3 indicates an extension direction for a (1-210) plane.

As illustrated in FIG. 4, the (11-20) plane of the substrate 1 is orthogonal of the (0001) plane that forms the first surface 1A. The (11-20) plane of the substrate 1 is also orthogonal to a (1-100) plane (“m” plane). “Orthogonal” here means that the angle respectively formed by two planes is greater than or equal to 80° and less than or equal to 100°.

<Method of Manufacturing Semiconductor Light-Emitting Element>

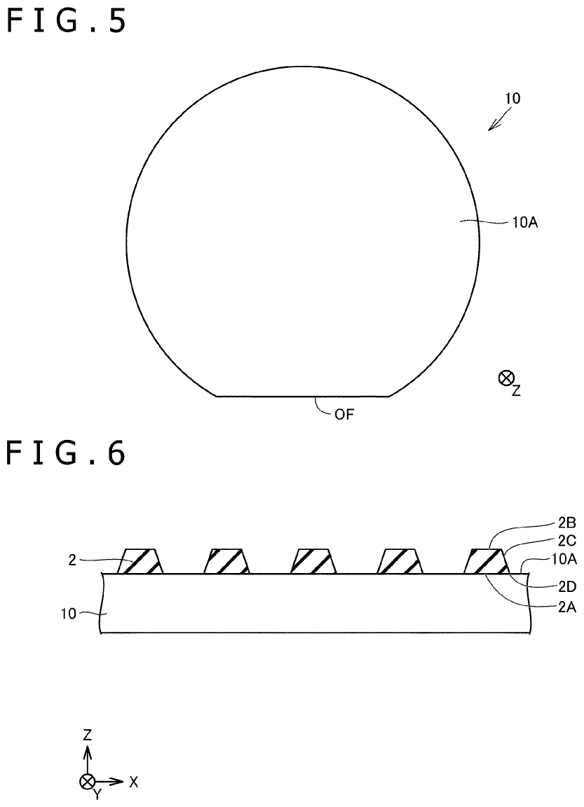

With reference to FIG. 5 through FIG. 12, description is given below regarding an example of a method of manufacturing the semiconductor light-emitting element 100.

Firstly, as illustrated in FIG. 5, a wafer 10 is prepared as the substrate 1 which has a hexagonal crystal structure. The wafer 10 has a hexagonal crystal structure. The wafer 10 has a main surface 10A and an orientation flat (OF). The main surface 10A is a (0001) plane (“c” plane) of the hexagonal crystal structure. The orientation flat is orthogonal to the main surface 10A. The orientation flat is an (11-20) plane (“a” plane) of the hexagonal crystal structure. Note that orientation error is permitted for the plane orientation of the main surface 10A, the same as for the first surface 1A. A material included in the main surface 10A of the wafer 10 may be any material having a hexagonal crystal structure, but, for example, includes sapphire, SiC, GaN, or SCAM.

Secondly, as illustrated in FIG. 6, the plurality of protrusions 2 are formed on the main surface 10A of the wafer 10. The plurality of protrusions 2 are, for example, formed by patterning a film deposited onto the main surface 10A. A material included in the film includes at least one selected from the group consisting of SiO₂, Si₃N₄, silicon oxynitride (SiON), TiO₂, Al₂O₃, and MgF₂. A film formation method for the method is not particularly limited, but, for example, is chemical vapor deposition (CVD) or a physical vapor deposition (PVD) method such as sputtering. The patterning method for the film is not particularly limited as long as it is possible to form the plurality of protrusions 2 which have the cross-sectional shape illustrated in FIG. 1 and are arranged as illustrated in FIG. 2 and FIG. 3. The patterning method for the film is, for example, a dry etching method that uses a mask pattern formed by photolithography.

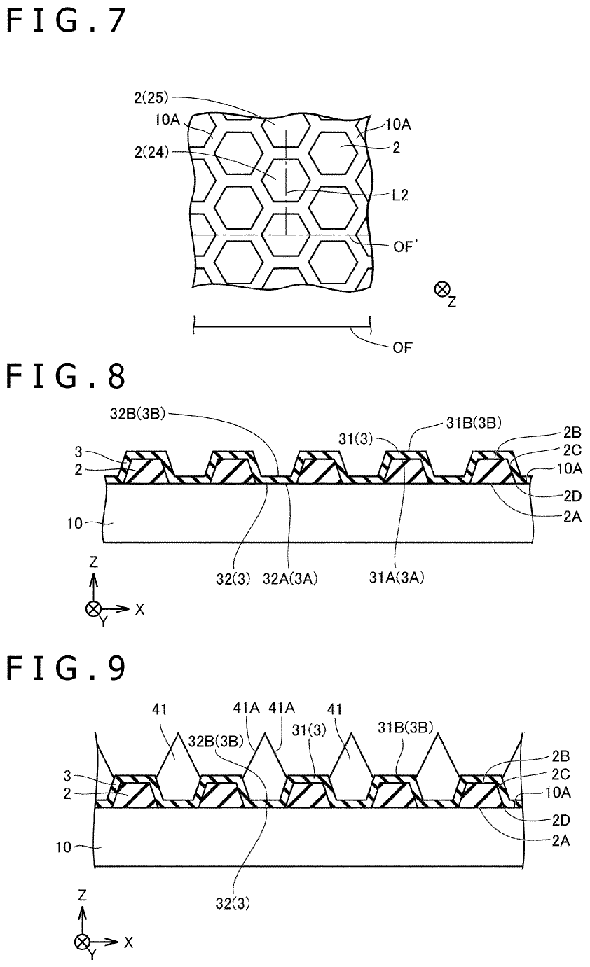

As illustrated in FIG. 7, when the main surface 10A is in a plan view, an imaginary straight line L2 passing through the center of each of a fourth protrusion 24 and a fifth protrusion 25 is orthogonal to an imaginary straight line OF′ parallel to the orientation flat OF. “Orthogonal” here means that the angle the imaginary straight line L2 forms with respect to the imaginary straight line OF′ in the plan view is greater than or equal to 80° and less than or equal to 100°. The angle the imaginary straight line L2 forms with respect to the imaginary straight line OF′ in the plan view is desirably greater than or equal to 85° and less than or equal to 95°.

Thirdly, as illustrated in FIG. 8, the buffer layer 3 is formed on the plurality of protrusions 2 and the first surface 1A exposed between the plurality of protrusions 2. A material included in the buffer layer 3 is Aln, for example. A method for forming the buffer layer 3 is organometallic vapor phase epitaxy (metal organic chemical vapor deposition (MOCVD) or metal organic vapor phase epitaxy (MOVPE)), for example. In this step, portions respectively deposited on the plurality of protrusions 2 become the first portions 31 of the buffer layer 3, and portions respectively deposited between two adjacent protrusions 2 become the second portions 32 of the buffer layer 3.

Fourthly, steps respectively illustrated in FIG. 9 through FIG. 12 are successively performed in order on the basis of the ELOG method to thereby successively grow the plurality of three-dimensional growth layers 41, the plurality of first two-dimensional growth layers 42, and the second two-dimensional growth layer 43 in this order, and as a result the n-type semiconductor layer 4 is formed on the top surface 3B of the buffer layer 3. A method for growing each of the plurality of three-dimensional growth layers 41, the plurality of first two-dimensional growth layers 42, and the second two-dimensional growth layer 43 is MOCVD, for example. In a case where an n-type impurity is Si, trimethyl gallium (TMG), ammonia (NH₃), and silane (SiH₄) can be used as raw material gases.

Firstly, as illustrated in FIG. 9, the plurality of three-dimensional growth layers 41 are selectively grown on the top surface 32B of each second portion 32 of the buffer layer 3. The present step is, for example, performed after performing thermal cleaning of the wafer 10 on which the buffer layer 3 has been formed in the previous step.

Each of the plurality of three-dimensional growth layers 41 has a hexagonal crystal structure. A material included in each of the plurality of three-dimensional growth layers 41 is GaN, for example. In the plan view, a unit cell for a (0001) plane in the hexagonal crystal structure of each of the plurality of three-dimensional growth layers 41 is rotated by 30° with respect to the unit cell of the (0001) plane of the hexagonal crystal structure of the substrate 1 (refer to FIG. 13). In FIG. 13, m1 indicates a unit cell for the (0001) plane of sapphire, and m2 indicates a unit cell for the (0001) plane of GaN. In FIG. 13, a plurality of circles respectively indicate Al atoms and O atoms in sapphire. Each of the plurality of three-dimensional growth layers 41 formed in this step have a protruding portion that protrudes upward from a first portion 31 of the buffer layer 3. The protruding portion of each three-dimensional growth layer 41 has a pair of side surfaces (facets 41A) that are inclined with respect to the first surface 1A.

Next, as illustrated in FIG. 10, the plurality of first two-dimensional growth layers 42 are respectively grown (lateral growth) on the top surface 31B of a first portion 31 of the buffer layer 3 so as to be embedded between the plurality of three-dimensional growth layers 41. Each of the plurality of first two-dimensional growth layers 42 is mainly grown, from each facet 41A of the plurality of three-dimensional growth layers 41, in a direction along the main surface 10A. At this time, variation of the growth rate in the lateral direction is suppressed. Each growth plane for the plurality of first two-dimensional growth layers 42 is aligned with a (10-12) plane or a (10-11) plane for the hexagonal crystal structure. Partway through the lateral growth, a surface surround by the (10-12) plane or the (10-11) plane of the hexagonal crystal structure is formed. Partway through the lateral growth, a plurality of surfaces surrounded by the growth planes of each of the plurality of first two-dimensional growth layers 42 are formed. The height of the plurality of surfaces with respect to the main surface 10A become equal to each other.

As illustrated in FIG. 11, one of a pair of first two-dimensional growth layers 42 that grow in mutually reverse directions on one first portion 31 ultimately unites with the other. The lateral growth progresses by continuing successive growth after the plurality of three-dimensional growth layers 41 illustrated in FIG. 9 are grown. As illustrated in FIG. 11, the plurality of three-dimensional growth layers 41 and the plurality of first two-dimensional growth layers 42 cover the top surface 3B of the buffer layer 3. The top surfaces of each of the plurality of first two-dimensional growth layers 42 are formed so as to extend out to each other. The top surfaces of each of the plurality of first two-dimensional growth layers 42 are (0001) planes.

Next, as illustrated in FIG. 12, the second two-dimensional growth layer 43 is grown on each of the plurality of three-dimensional growth layers 41 and the plurality of first two-dimensional growth layers 42. The second two-dimensional growth layer 43 is grown upward from the top surface of each of the plurality of first two-dimensional growth layers 42.

In this manner, the plurality of three-dimensional growth layers 41, the plurality of first two-dimensional growth layers 42, and the second two-dimensional growth layer 43 are successively grown in this order, whereby the n-type semiconductor layer 4 is formed. A portion of a top surface of 43B of the n-type semiconductor layer 4 becomes the first top surface 4B1 of the n-type semiconductor layer 4 in the semiconductor light-emitting element 100. The top surface 43B in the n-type semiconductor layer 4 is the (0001) plane. As illustrated in FIG. 13, a unit cell for the (0001) plane of the hexagonal crystal structure of the n-type semiconductor layer 4 grown as described above is rotated by 30° with respect to the unit cell of the (0001) plane of the hexagonal crystal structure of the wafer 10 (substrate 1).

Fifthly, the active layer 5 is formed on the n-type semiconductor layer 4. In the present step, for example, a barrier layer and a well layer are alternatingly and successively formed, whereby the active layer 5 having a multi-quantum well structure is formed. A method of forming each barrier layer and well layer is MOCVD, for example.

Sixthly, the p-type semiconductor layer 6 is formed on the active layer 5. A method of forming the p-type semiconductor layer 6 is MOCVD, for example.

Seventhly, the first electrode section 7 is formed on the p-type semiconductor layer 6. A method of forming the first electrode section 7 is PVD, for example.

Eighthly, the second top surface 4B2 is formed in the n-type semiconductor layer 4. In the present step, a partial region for each of the first electrode section 7, the p-type semiconductor layer 6, and the active layer 5 in the plan view is removed in the order described above, and a portion of the second two-dimensional growth layer 43 directly below this partial region is also removed. As a result, the second top surface 4B2 is formed as an exposed surface of the second two-dimensional growth layer 43. In the present step, a method of partially removing each of the first electrode section 7, the p-type semiconductor layer 6, the active layer 5, and the n-type semiconductor layer 4 is a dry etching method, for example.

Ninthly, the second electrode section 8 is formed on the first electrode section 7, and the third electrode section 9 is formed on the second top surface 4B2 of the n-type semiconductor layer 4. In the present step, for example, after a conductor film that is to be the second electrode section 8 and the third electrode section 9 is deposited on the first electrode section 7 and the second top surface 4B2, the conductor film is patterned. A method of depositing the conductor film is PVD, for example. The patterning method for the conductor film is, for example, a dry etching method that uses a mask pattern formed by photolithography.

Tenthly, the wafer 10 is diced. As a result, a plurality of semiconductor light-emitting elements 100 formed on the wafer 10 are singulated, whereby the semiconductor light-emitting element 100 illustrated in FIG. 1 is manufactured.

<Effects>

In the semiconductor light-emitting element 100, the substrate 1 has a hexagonal crystal structure. The first surface 1A of the substrate 1 is a (0001) plane (“c” plane) of the hexagonal crystal structure. The n-type semiconductor layer 4 has a hexagonal crystal structure. When the first surface 1A is in a plan view, an imaginary straight line that passes through the centers of the first protrusion 21 and the second protrusion 22, which are adjacent to each other and are from among the plurality of protrusions 2, is orthogonal to the (11-20) plane of the hexagonal crystal structure of the substrate.

For example, a material included in the first surface 1A of the substrate 1 includes sapphire. A material included in the n-type semiconductor layer 4 includes gallium nitride. When the first surface 1A is in a plan view, the (1-100) plane of the n-type semiconductor layer 4 is inclined, forming a 30° angle with respect to the (1-100) plane of the substrate 1.

The first top surface 4B1 (second surface) of the n-type semiconductor layer 4 in such a semiconductor light-emitting element 100 is flat in comparison to the top surface of the n-type semiconductor layer 4 in the semiconductor light-emitting element, for which an imaginary straight line passing through centers of a first protrusion and a second protrusion that are adjacent to each other and from among a plurality of protrusions is parallel to the (11-20) plane of the hexagonal crystal structure of the substrate. The reason therefor is as follows.

In a case of growing an n-type semiconductor layer having a hexagonal crystal structure on the main surface of a wafer having a hexagonal crystal structure, there are cases where, according to the relation between the respective lattice constants of the n-type semiconductor layer and the wafer, the crystal orientation of the n-type semiconductor layer is rotated by 30° with respect to the crystal orientation of the wafer. As an example, a case in which the GaN described above is grown on the main surface of a sapphire substrate can be given. In such a case, the “a” plane of the n-type semiconductor layer is rotated by 30° with respect to the “a” plane of the wafer, and the “m” plane of n-type semiconductor layer is rotated by 30° with respect to the “m” plane of the wafer.

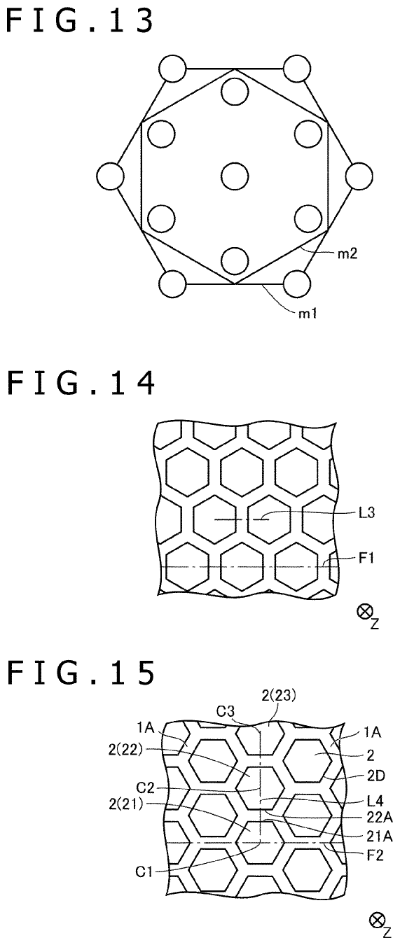

As illustrated in FIG. 14, in a semiconductor light-emitting element in which an imaginary straight line L3 passing through the centers of a first protrusion and a second protrusion that are adjacent to each other and are from among a plurality of protrusions is made to be parallel to the (11-20) plane (refer to broken line F1) of the hexagonal crystal structure of a substrate, variation arises in the growth rate, in the lateral direction, in a process for lateral growth of the n-type semiconductor layer, even if each of a plurality of growth planes are unified with the (10-12) plane or the (10-11) plane of the hexagonal crystal structure.

This is because, in the plan view, due to the plurality of growth planes not being orthogonal to the imaginary straight line and each of the plurality of growth planes not facing each other, variation arises in an amount of time required for growth planes to unite with one another in the lateral growth process. As a result, (0001) planes having varied height with respect to the main surface of the wafer are formed as a plurality of surfaces surrounded by the plurality of growth planes. As a result, due to the variation of the above-mentioned height, steps are formed on the top surface of the n-type semiconductor layer that is ultimately formed. In this case, an arithmetic mean roughness Ra stipulated in JIS B 0601 for the top surface of the n-type semiconductor layer that is in contact with the active layer becomes greater than 0.1 μm. In such a semiconductor light-emitting element, a decrease of light-emission efficiency and an increase in a leakage current arise due to the occurrence of crystal defects due to the steps described above.

In contrast to this, for the semiconductor light-emitting element 100, it is less likely for variation in the growth rate, in the lateral direction, in a lateral growth process for the n-type semiconductor layer 4 to arise, as described above. This is because, in the plan view, due to the plurality of growth planes being orthogonal to the above-mentioned imaginary straight line and each of the plurality of growth planes facing each other, variation is less likely to arise in an amount of time required for growth planes to unite with one another in the lateral growth process. As a result, the heights of the plurality of surfaces surrounded by the plurality of growth planes are aligned with respect to the main surface of the wafer, and the first top surface 4B1 of the n-type semiconductor layer 4 is flat in comparison to the top surface of the n-type semiconductor layer 4 in the semiconductor light-emitting element. An arithmetic mean roughness Ra, which is stipulated in JIS B 0601, for the first top surface 4B1 of the n-type semiconductor layer 4 becomes less than or equal to 0.1 mm. In such a semiconductor light-emitting element 100, it is possible to reduce crystal defects and it is possible to improve light-emission efficiency and reduce leakage current, in comparison to the semiconductor light-emitting element described above.

In the semiconductor light-emitting element 100, a dimension (thickness) for the buffer layer 3 in a direction orthogonal to the first surface 1A is greater than or equal to 5 nm and less than or equal to 200 nm.

If the thickness of the buffer layer 3 is greater than or equal to 5 nm and greater than or equal to 200 nm, it is possible to reduce crystal defects in the n-type semiconductor layer and improve crystal quality, in comparison to a case in which the thickness of the buffer layer 3 is less than 5 nm or a case in which the thickness of the buffer layer 3 is greater than 200 nm. The crystal quality can be evaluated by using an X-ray diffractometer.

Note that, in the semiconductor light-emitting element 100, a material included in the first surface 1A of the substrate 1 may be any material having a hexagonal crystal structure, but, for example, may include SiC, GaN, or ScAlMgO₄. In this manner, when the first surface 1A is in a plan view, if the (1-100) plane of the n-type semiconductor layer 4 is inclined to form a 30° angle with respect to the (1-100) plane of the substrate 1, an effect similar to the case where the material included in the first surface 1A of the substrate 1 includes sapphire is achieved.

### Second Embodiment

A semiconductor light-emitting element according to a second embodiment includes a configuration that is basically similar to that of the semiconductor light-emitting element 100 according to the first embodiment and achieves a similar effect thereto, but differs to the semiconductor light-emitting element 100 in that the substrate 1 has a diamond crystal structure. Description is mainly given below for points where the semiconductor light-emitting element according to the second embodiment differs to the semiconductor light-emitting element 100.

A material included in the first surface 1A of the substrate 1 has a diamond crystal structure. The first surface 1A of the substrate 1 is a (111) plane of the diamond crystal structure. Note that an orientation error with respect to the (111) plane is permitted for the plane orientation of the first surface 1A. An absolute value for permitted orientation error is greater than or equal to 0° and less than or equal to 10°. A material included in the first surface 1A of the substrate 1 may be any material having a diamond crystal structure, but includes Si, for example.

In a plan view, the plurality of protrusions 2 are periodically disposed in two dimensions. A plan view means a field of view in which the first surface 1A is viewed from above. In the present embodiment, a plan view means a field of view seen from a direction orthogonal to the (111) plane of the diamond crystal structure of the substrate 1.

With reference to FIG. 15, the plurality of protrusions 2 have a first protrusion 21 and a second protrusion 22 that is adjacent to the first protrusion 21. In FIG. 15, a first broken line L4 indicates an imaginary straight line that passes through a center C1 of the first protrusion 21 and a center C2 of the second protrusion 22, in a plan view. A second broken line F2 indicates an extension direction for a (1-12) plane of the diamond crystal structure of the substrate 1, in the plan view. The first broken line L4 and the second broken line F2 illustrated in FIG. 15 can be expressed on an image obtained by using the SEM to observe the semiconductor light-emitting element 100, for example, similarly to the first broken line L1 and the second broken line F1 illustrated in FIG. 2.

As illustrated in FIG. 15, the first broken line L4 is orthogonal to the second broken line F2 in the plan view. In other words, the imaginary straight line L4 that passes through the centers of the first protrusion 21 and the second protrusion 22 is orthogonal to the (1-12) plane of the diamond crystal structure held by the substrate 1. “Orthogonal” here means that the angle the imaginary straight line L4 forms with respect to the (1-12) plane in the plan view is greater than or equal to 80° and less than or equal to 100°. The angle the imaginary straight line L4 forms with respect to the (1-12) plane in the plan view is desirably greater than or equal to 85° and less than or equal to 95°.

A method of manufacturing the semiconductor light-emitting element according to the second embodiment includes a composition that is basically similar to the method of manufacturing the semiconductor light-emitting element 100, but differs to the method of manufacturing the semiconductor light-emitting element 100 in that a wafer having a diamond crystal structure is prepared as the substrate 1.

This wafer has an orientation flat that is orthogonal to the (111) plane. The orientation flat is the (1-10) plane of the diamond crystal structure. A material included in the main surface 10A of the wafer 10 may be any material having a diamond crystal structure, but includes Si, for example.

The plurality of protrusions 2 are formed such that an imaginary straight line L4 that passes through the centers of the first protrusion 21 and the second protrusion 22 is orthogonal to the (1-12) plane of the diamond crystal structure of the wafer.

Subsequently, the buffer layer 3 and the n-type semiconductor layer 4 are formed in this order. The n-type semiconductor layer 4 basically grows similarly to the n-type semiconductor layer 4 in the first embodiment, but differs to the n-type semiconductor layer 4 in the first embodiment in the following point.

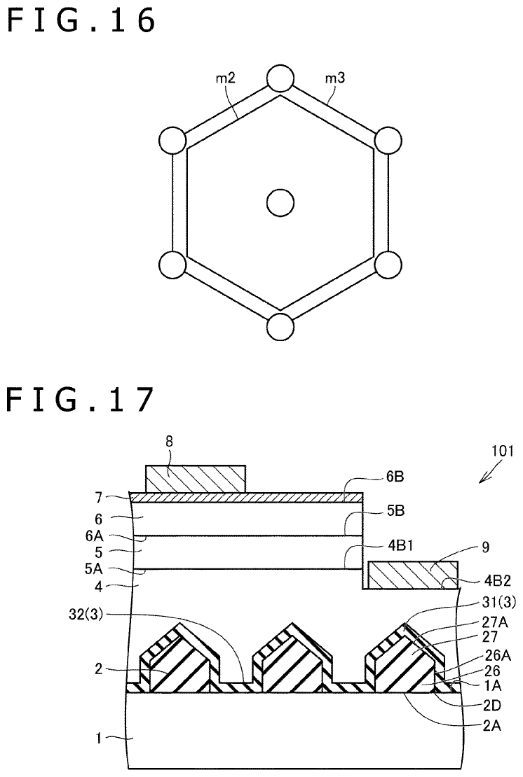

In the plan view, a unit cell for a (0001) plane in the hexagonal crystal structure of each of the plurality of three-dimensional growth layers 41 is parallel with respect to the unit cell of the (111) plane of the diamond crystal structure of the substrate 1 (refer to FIG. 16). In FIG. 16, m3 indicates a unit cell for the (111) plane of Si, and m2 indicates a unit cell for the (0001) plane of GaN. In FIG. 16, each of the plurality of circles indicates an Si atom on the (111) plane.

Subsequently, the active layer 5 and the p-type semiconductor layer 6 are formed similarly to in the method of manufacturing the semiconductor light-emitting element 100, whereby the semiconductor light-emitting element according to the second embodiment can be manufactured.

<Effects>

In the semiconductor light-emitting element according to the second embodiment, the substrate 1 has a diamond crystal structure. The first surface 1A of the substrate 1 is a (111) plane of the diamond crystal structure. The n-type semiconductor layer 4 has a hexagonal crystal structure. When the first surface 1A is in a plan view, an imaginary straight line that passes through the centers of the first protrusion 21 and the second protrusion 22, which are adjacent to each other and are from among the plurality of protrusions 2, is orthogonal to the (1-12) plane of the diamond crystal structure of the substrate 1.

For example, a material included in the first surface 1A of the substrate 1 includes Si. A material included in the n-type semiconductor layer 4 includes gallium nitride.

In the second embodiment, the first top surface 4B1 (second surface) of the n-type semiconductor layer 4 is flat in comparison to the top surface of the n-type semiconductor layer 4 in the semiconductor light-emitting element, for which an imaginary straight line passing through centers of a first protrusion and a second protrusion that are adjacent to each other and from among a plurality of protrusions is parallel to the (1-12) plane of the diamond crystal structure of the substrate. The reason therefor is as follows.

As described above, in a case of growing an n-type semiconductor layer having a hexagonal crystal structure on the main surface of a wafer having a diamond crystal structure, there are cases where a unit cell of a (0001) plane of the n-type semiconductor layer is parallel to a unit cell of a (111) plane of the diamond crystal structure of the substrate 1. As an example, a case in which the GaN described above is grown on the main surface of a Si substrate can be given.

In a semiconductor light-emitting element in which an imaginary straight line passing through the centers of a first protrusion and a second protrusion that are adjacent to each other and are from among a plurality of protrusions is made to be parallel to the (1-12) plane of the diamond crystal structure of a substrate, variation arises in the growth rate, in the lateral direction, in a process for lateral growth of the n-type semiconductor layer, even if each of a plurality of growth planes are unified with the (10-12) plane or the (10-11) plane of the hexagonal crystal structure.

This is because, in the plan view, due to the plurality of growth planes not being orthogonal to the imaginary straight line and each of the plurality of growth planes not facing each other, variation arises in an amount of time required for growth planes to unite with one another in the lateral growth process. As a result, (0001) planes having varied height with respect to the main surface of the wafer are formed as a plurality of surfaces surrounded by the plurality of growth planes. As a result, due to the variation of the above-mentioned height, steps are formed on the top surface of the n-type semiconductor layer that is ultimately formed. In this case, an arithmetic mean roughness Ra stipulated in JIS B 0601 for the top surface of the n-type semiconductor layer that is in contact with the active layer becomes greater than 0.1 μm. In such a semiconductor light-emitting element, a decrease of light-emission efficiency and an increase in a leakage current arise due to the occurrence of crystal defects due to the steps described above.

In contrast to this, for the semiconductor light-emitting element according to the second embodiment, it is less likely for variation in the growth rate, in the lateral direction, in a lateral growth process for the n-type semiconductor layer 4 to arise. This is because, in the plan view, due to the plurality of growth planes being orthogonal to the above-mentioned imaginary straight line and each of the plurality of growth planes facing each other, variation is less likely to arise in an amount of time required for growth planes to unite with one another in the lateral growth process. As a result, the heights of the plurality of surfaces surrounded by the plurality of growth planes are aligned with respect to the main surface of the wafer, and the first top surface 4B1 of the n-type semiconductor layer 4 is flat in comparison to the top surface of the n-type semiconductor layer 4 in the semiconductor light-emitting element. An arithmetic mean roughness Ra, which is stipulated in JIS B 0601, for the first top surface 4B1 of the n-type semiconductor layer 4 becomes less than or equal to 0.1 μm. As a result, in the semiconductor light-emitting element according to the second embodiment, it is possible to reduce crystal defects and it is possible to improve light-emission efficiency and reduce leakage current, in comparison to a semiconductor light-emitting element, for which an imaginary straight line passing through centers of a first protrusion and a second protrusion, which are adjacent to each other and are from among a plurality of protrusions, is parallel to the (1-12) plane of the diamond crystal structure of the substrate.

### Third Embodiment

A semiconductor light-emitting element 101 according to a third embodiment includes a configuration that is basically similar to that of the semiconductor light-emitting element according to the first embodiment or second embodiment and achieves a similar effect thereto, but differs to the semiconductor light-emitting element according to the first embodiment or second embodiment in that each of the plurality of protrusions 2 includes a lower section 26 and an upper section 27 and that the upper section 27 has a tapered shape in a cross-section along the Z direction. Description is mainly given below for points where the semiconductor light-emitting element 101 according to the third embodiment differs to a semiconductor light-emitting element according to the first embodiment or second embodiment.

In each of the plurality of protrusions 2, the lower section 26 is connected to the first surface 1A. The lower section 26 has a bottom surface 2A in contact with the first surface 1A, and an outer peripheral surface 26A that extends in a direction that intersects with the first surface 1A. In each of the plurality of protrusions 2, the upper section 27 is disposed above the lower section 26. When the plurality of protrusions 2 are in a cross-sectional view in a cross-section along the Z direction, each upper section 27 has an inclined surface 27A that is connected to the outer peripheral surface 26A of the lower section 26 and is inclined with respect to the outer peripheral surface 26A. In this cross-sectional view, the inclined surface 27A has a shape that tapers as a distance from the first surface 1A of the substrate 1 increases. The inclined surface 27A and the outer peripheral surface 26A protrude upward from the first surface 1A and are in contact with the buffer layer 3.

The outer peripheral surface 26A is orthogonal to the first surface 1A. “Orthogonal” here means that an interior angle between the outer peripheral surface 26A and the bottom surface 2A is greater than or equal to 70° and less than or equal to 90°. The interior angle between the inclined surface 27A and the outer peripheral surface 26A is an obtuse angle. The interior angle between the inclined surface 27A and the outer peripheral surface 26A is greater than or equal to 120° and less than or equal to 150°.

In the plan view, the external shape of each of the plurality of protrusions 2 may be any shape that does not inhibit formation of the n-type semiconductor layer 4 using the ELOG method, and is a hexagonal shape, for example. In other words, the external shape of each outer peripheral surface 26A and inclined surface 27A of each of the plurality of protrusions 2 is a hexagonal shape, for example.

Note that, in the plan view, the external shape of each of the plurality of protrusions 2 may be a triangular shape, a square shape, a rectangular shape, a circular shape, or an oval shape, for example.

The bottom surface of each first portion 31 of the buffer layer 3 has a region that is in contact with respective outer peripheral surfaces 26A of the plurality of protrusions 2, and a region that is in contact with respective inclined surfaces 27A of the plurality of protrusions 2.

For each of the plurality of protrusions 2, the dimension in the Z direction for the lower section 26 is less than or equal to ⅘ of the entire dimension in the Z direction of the protrusion 2. The dimension in the Z direction of the upper section 27 is greater than or equal to ⅕ of the entire dimension in the Z direction of the protrusion 2. For each of the plurality of protrusions 2, the dimension in the Z direction of the lower section 26 is desirably greater than or equal to ¼ and less than or equal to ¾, of the entire dimension in the Z direction of the protrusion 2.

In a case where an optical film thickness of the plurality of protrusions 2 is sufficiently thick with respect to the emission wavelength of the semiconductor light-emitting element, the plurality of protrusions 2 reflect and refract light emitted into the element from the active layer 5, whereby the direction of light emitted from the active layer 5 into the element (substrate 1 side) is changed to be outward from the element, and light extraction efficiency is improved. When in a plan view, the higher the ratio that the protrusions 2 having a sufficient optical film thickness have with respect to the surface area occupied by the first surface 1A, the greater the effect of the above-mentioned action by the protrusions 2 and the greater the light extraction efficiency.

In a case where each of the plurality of protrusions 2 does not have the lower section 26 and does not have the above-mentioned tapered shape in a cross-sectional view, as with the semiconductor light-emitting element 100, a portion lacking a thickness to cause the above-mentioned action is formed on the outer peripheral section of each protrusion 2 when in a plan view.

In contrast to this, in the semiconductor light-emitting element 101, each protrusion 2 has the above-mentioned tapered shape in a cross-sectional view, and the outer peripheral section of each protrusion 2 when in a plan view can become a portion having the sufficient optical film thickness to cause the above-mentioned action. Accordingly, in comparison to the semiconductor light-emitting element 100, for the semiconductor light-emitting element 101 it is possible for a ratio that protrusions 2 having the sufficient optical film thickness have when in a plan view with respect to the surface area occupied by the first surface 1A to be increased and for the light extraction efficiency to be increased.

In particular, in the semiconductor light-emitting element 101, because an outer peripheral surface 26A of each lower section 26 of the plurality of protrusions 2 is orthogonal to the first surface 1A, an outermost circumferential section of each protrusion 2 when in a plan view also thickens in comparison to a case where each lower section 26 has a tapered shape in a cross-sectional view. As a result, because the entirety of each protrusion 2 when in a plan view can be a portion that has the sufficient optical film thickness to cause the above-mentioned action in the semiconductor light-emitting element 101, the light extraction efficiency can be increased in comparison to a semiconductor light-emitting element in which each lower section 26 has a tapered shape in a cross-sectional view.

<Variation>

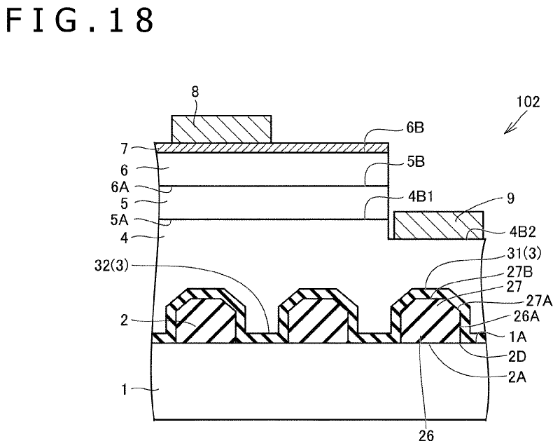

As illustrated in FIG. 18, in the semiconductor light-emitting element 101, the upper section 27 of each of the plurality of protrusions 2 may also have a top surface 27B that is connected to the inclined surfaces 27A and is parallel to the first surface 1A. “Parallel” here means an absolute value of an angle of inclination that the top surface 27B forms with respect to the first surface 1A is greater than or equal to 0° and less than or equal to 10°. The semiconductor light-emitting element 101 illustrates in FIG. 18 achieves a similar effect to the semiconductor light-emitting element 101 illustrated in FIG. 17.

Description has been given regarding embodiments of the present technology as above, but it is possible to perform various modifications to the embodiments described above. In addition, the scope of the present technology is not limited to the embodiments described above. The scope of the present technology is indicated by the scope of the claims and is intended to include all changes within the meaning and scope equivalent to the scope of the claims.

What is claimed is:

1. A semiconductor light-emitting element comprising:
a substrate having a first surface;
a plurality of protrusions disposed, with spacing opened between one another, on the first surface;
a buffer layer disposed to cover the plurality of protrusions and the first surface positioned between the plurality of protrusions, a dimension of the buffer layer in a first direction orthogonal to the first surface being smaller than a dimension in the first direction of each of the plurality of protrusions;
an n-type semiconductor layer that is disposed on the buffer layer and is doped with an n-type impurity;
an active layer disposed on the n-type semiconductor layer; and
a p-type semiconductor layer that is disposed on the active layer and is doped with a p-type impurity, wherein
the substrate has a hexagonal crystal structure or a diamond crystal structure,
the first surface is a (0001) plane of the hexagonal crystal structure or a (111) plane of the diamond crystal structure,
the n-type semiconductor layer has a hexagonal crystal structure, and,
when the first surface is in a plan view, an imaginary straight line passing through respective centers of a first protrusion and a second protrusion that are adjacent to each other and are from among the plurality of protrusions is orthogonal to an (11-20) plane of the hexagonal crystal structure or a (1-12) plane of the diamond crystal structure of the substrate.

2. The semiconductor light-emitting element according to claim 1, wherein
each of the plurality of protrusions includes a lower section connected to the first surface and an upper section disposed on the lower section,
when the plurality of protrusions are in a cross-sectional view in a cross-section along the first direction, the upper section has an inclined surface that is connected to an outer peripheral surface of the lower section and is inclined with respect to the outer peripheral surface, and
an interior angle between the inclined surface and the outer peripheral surface is an obtuse angle.

3. The semiconductor light-emitting element according to claim 2, wherein the outer peripheral surface of the lower section of each of the plurality of protrusions is orthogonal to the first surface.

4. The semiconductor light-emitting element according to claim 2, wherein the upper section of each of the plurality of protrusions also has a top surface that is connected to the inclined surface and is parallel to the first surface.

5. The semiconductor light-emitting element according to claim 1, wherein a dimension of the buffer layer in a direction orthogonal to the first surface is greater than or equal to 5 nm and less than or equal to 200 nm.

6. The semiconductor light-emitting element according to claim 1, wherein a material included in the first surface of the substrate includes sapphire, silicon, silicon carbide, gallium nitride, or ScAlMgO₄.

7. The semiconductor light-emitting element according to claim 1, wherein
a material included in the first surface of the substrate includes sapphire,
a material included in the n-type semiconductor layer includes gallium nitride, and,
when the first surface is in a plan view, a (1-100) plane of the n-type semiconductor layer is inclined by forming a 30° angle with respect to a (1-100) plane of the substrate.

8. The semiconductor light-emitting element according to claim 1, wherein a material included in the plurality of protrusions includes at least one selected from silicon oxide, silicon nitride, silicon oxynitride, titanium oxide, aluminum oxide, and magnesium fluoride.

9. The semiconductor light-emitting element according to claim 1, wherein
the n-type semiconductor layer has a second surface in contact with the active layer, and
the second surface is flat.
